(19) United States
(12) Patent Application Publication
(10) Pub. No.: US 2026/0005018 A1
(43) Pub. Date: Jan. 1, 2026

(54) GAPFILL METHOD, SYSTEM AND APPARATUS

(71) Applicant: ASM IP Holding B.V., Almere (NL)

(72) Inventors: Yu Xu, Mesa, AZ (US); Gyunghyun Ryu, Chandler, AZ (US); Devika Choudhury, Chandler, AZ (US); Michael Schmotzer, Chandler, AZ (US); Mihaela Balseanu, Scottsdale, AZ (US)

(21) Appl. No.: 19/248,647

(22) Filed: Jun. 25, 2025

Related U.S. Application Data
(60) Provisional application No. 63/665,481, filed on Jun. 28, 2024.

(51) Int. Cl. H01L 21/02; C23C 16/04; C23C 16/40; C23C 16/455; H01J 37/32

(52) U.S. Cl. CPC H01L 21/02304; C23C 16/04; C23C 16/403; C23C 16/45534; C23C 16/45553; H01J 37/32449; H01L 21/02178; H01L 21/0228; H01J 2237/332

(57) ABSTRACT

A method, system and apparatus for depositing an oxide in a recess of a substrate is disclosed and includes a) providing the substrate in a chamber, the substrate including at least one opening to the recess, b) initially pulsing a precursor into the chamber to preferentially chemisorb in a first area, c) pulsing an oxygen species into the chamber to form a first oxide layer in the first area upon contact with the chemisorbed precursor, d) pulsing an inhibitor into the chamber to preferentially deposit an inhibitor layer on the first oxide layer, e) pulsing the precursor into the chamber to chemisorb to a second area, and/or f) pulsing the oxygen species into the chamber to form a second oxide layer in the second area upon contact with the chemisorbed precursor.

### CROSS-REFERENCE TO RELATED APPLICATIONS

This application is a nonprovisional of, and claims priority to and the benefit of, U.S. Provisional Patent Application No. 63/665,481, filed Jun. 28, 2024 and entitled “GAPFILL METHOD, SYSTEM AND APPARATUS,” which is hereby incorporated by reference herein.

### FIELD OF THE DISCLOSURE

The present disclosure generally relates to methods and systems suitable for forming electronic devices. More particularly, the disclosure relates to methods and systems that can be used for depositing a material in gaps, trenches, and the like.

### BACKGROUND OF THE DISCLOSURE

The scaling of semiconductor devices has led to significant improvements in speed and density of integrated circuits. However, with miniaturization of wiring pitch in large scale integration devices, void-free filling of high aspect ratio gaps or trenches (e.g., trenches having an aspect ratio of three or higher) becomes increasingly difficult due to limitations of existing deposition processes. Therefore, there is a need for processes that efficiently fill high aspect ratio features, e.g., gaps such as trenches on semiconductor substrates, for example in the context of logic and/or memory devices. There is a particular need for processes that efficiently fill high aspect ratio features with conductive materials that minimize seam and gap formation.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

In one aspect, a method for depositing an oxide in a recess of a substrate, includes a) providing the substrate in a chamber, the substrate including at least one opening to the recess, b) initially pulsing a precursor into the chamber to preferentially chemisorb in a first area, c) pulsing an oxygen species into the chamber to form a first oxide layer in the first area upon contact with the chemisorbed precursor, d) pulsing an inhibitor into the chamber to preferentially deposit an inhibitor layer on the first oxide layer, e) pulsing the precursor into the chamber to chemisorb to a second area, f) pulsing the oxygen species into the chamber to form a second oxide layer in the second area upon contact with the chemisorbed precursor, and g) repeating one or more steps b)-c) until the first oxide layer is deposited to a first desired thickness in the first area. The method also includes step h) repeating step d) until the inhibitor layer is deposited to a second desired thickness in the first area. The method also includes step i) repeating steps e)-f) after deposition of the inhibitor until the second oxide layer is deposited to a third desired thickness in the second area. The method may also include where the first area is proximate to an opening of the recess. The method may also include where the second area is within the recess. The method may also include where the inhibitor is octadecylphosphonic acid. The method may also include where the precursor is a metal precursor. The method may also include where the oxide is a metal oxide. The method may also include where the oxygen species is H2O. The method may also include further includes pulsing an inert gas into the chamber to purge the chamber subsequent to one or more of steps b)-f). The method may also include further includes removing the inhibitor layer. The method may also include further includes exposing the substrate to H2 plasma, O3 or H2O to remove the inhibitor layer. The method may also include where the first desired thickness is less than 20 angstroms. The method may also include where the first desired thickness is less than 15 angstroms. The method may also include where the second desired thickness is equivalent to a height of the recess from an opening to a lower surface. The method may also include where the second desired thickness is equivalent to a length of the recess from a first opening to a second opening. The method may also include where the metal precursor is TMA. The method may also include where the metal oxide is aluminum oxide. A structure may be formed according to the above noted method, such structure may also include the substrate comprising silicon oxide where surfaces within the recess comprise silicon oxide. The structure may also include a semiconductor device having a finFET, GAA or CFET architecture.

For the purpose of summarizing the disclosure and the advantages achieved over the prior art, certain objects and advantages of the disclosure have been described herein above. Of course, it is to be understood that not necessarily all such objects or advantages can be achieved in accordance with any particular embodiment or example of the disclosure. Thus, for example, those skilled in the art will recognize that the examples disclosed herein can be carried out in a manner that achieves or optimizes one advantage or group of advantages as taught or suggested herein without necessarily achieving other objects or advantages as can be taught or suggested herein.

All of these examples are intended to be within the scope of the disclosure. These and other embodiments will become readily apparent to those skilled in the art from the following detailed description of certain examples having reference to the attached figures, the disclosure not being limited to any particular example(s) discussed.

### BRIEF DESCRIPTION OF THE DRAWING FIGURES

While the specification concludes with claims particularly pointing out and distinctly claiming what are regarded as embodiments or examples of the disclosure, the advantages of examples of the disclosure may be more readily ascertained from the description of certain examples of the disclosure when read in conjunction with the accompanying drawings. Elements with the like element numbering throughout the figures are intended to be the same.

FIG. 1 illustrates a schematic diagram of a reactor system, in accordance with an example of the present technology.

FIG. 2 illustrates a schematic diagram of a reactor system having multiple reaction chambers, in accordance with an example of the present technology.

FIG. 3 illustrates a device structure, in accordance with an example of the present technology.

FIG. 4 illustrates a device structure, in accordance with an example of the present technology.

FIG. 5 illustrates a device structure, in accordance with an example of the present technology.

FIG. 6A illustrates a processing method, in accordance with an example of the present technology.

FIG. 6B illustrates a processing method, in accordance with an example of the present technology.

FIG. 7 illustrates a processing method, in accordance with an example of the present technology.

FIG. 8 illustrates a processing method, in accordance with an example of the present technology.

FIG. 9A illustrates a device structure, in accordance with an example of the present technology.

FIG. 9B illustrates a processing method, in accordance with an example of the present technology.

### DETAILED DESCRIPTION

The detailed description of various examples herein makes reference to the accompanying drawings, which show the exemplary examples by way of illustration. While these exemplary examples are described in sufficient detail to enable those skilled in the art to practice the disclosure, it should be understood that other examples may be realized and that logical, chemical, and/or mechanical changes may be made without departing from the spirit and scope of the disclosure. Thus, the detailed description herein is presented for purposes of illustration only and not of limitation. For example, the steps recited in any of the method or process descriptions can be executed in any combination and/or order and are not limited to the combination and/or order presented. Further, one or more steps from one of the disclosed methods or processes can be combined with one or more steps from another of the disclosed methods or processes in any suitable combination and/or order. Moreover, any of the functions or steps can be outsourced to or performed by one or more third parties. Furthermore, any reference to singular includes plural examples, and any reference to more than one component can include a singular example.

Although certain embodiments and examples are disclosed below, it will be understood by those in the art that the disclosure extends beyond the specifically disclosed examples and/or uses of the disclosure and obvious modifications and equivalents thereof. Thus, it is intended that the scope of the disclosure should not be limited by the particular examples described herein.

The illustrations presented herein are not meant to be actual views of any particular material, apparatus, structure, or device, but are merely representations that are used to describe examples of the disclosure.

As used herein, the term “substrate” can refer to any underlying material or materials that may be used, or upon which, a device, a circuit, or a film/layer may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or (high-k) dielectric material layer overlying at least a portion of the bulk semiconductor material.

As used herein, the term “atomic layer deposition” (ALD) can refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) can subsequently be introduced into the process chamber for use in converting the chemisorbed precursor to the desired material on the deposition surface. Typically, this reactant is capable of further reaction with the precursor. Further, purging steps can also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) can refer to any process wherein a substrate is exposed to one or more volatile precursors, which react and/or decompose on a substrate surface to produce a desired deposition.

As used herein, the terms “layer,” “film,” and/or “thin film” can refer to any continuous or non-continuous structures and material deposited by the methods disclosed herein. For example, “layer,” “film,” and/or “thin film” could include 2D materials, nanorods, nanotubes, or nanoparticles or even partial or full molecular layers or partial or full atomic layers or clusters of atoms and/or molecules. “Layer,” “film,” and/or “thin film” can comprise material or a layer with pinholes, but still be at least partially continuous.

Further, in this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, or the like. Further, in this disclosure, the terms “including,” “constituted by” and “having” can refer independently to “typically or broadly comprising,” “comprising,” “consisting essentially of,” or “consisting of” in some examples. In this disclosure, any defined meanings do not necessarily exclude ordinary and customary meanings in some examples.

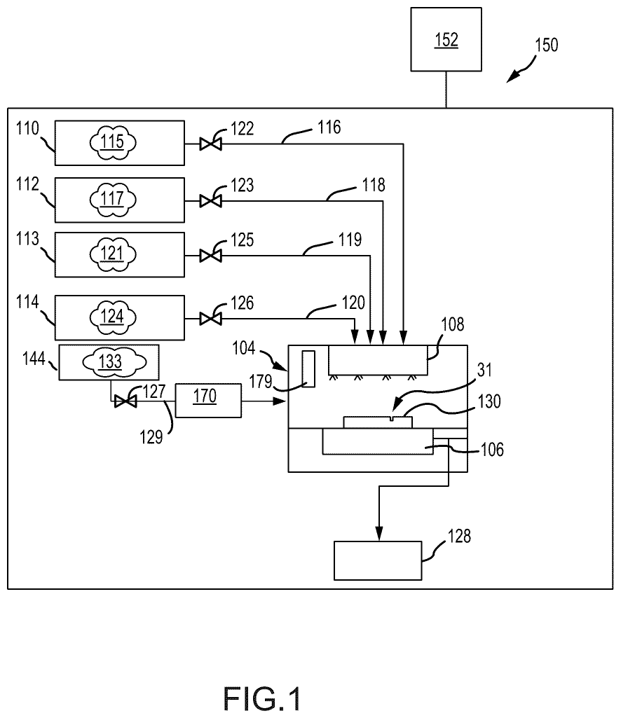

Referring now to FIG. 1, in various examples, a reactor system 150 can comprise a reaction chamber 104, a susceptor 106 to hold a substrate 130 (including at least one recess 31) during processing, a fluid distribution system 108 (e.g., a showerhead) to distribute one or more reactants to a surface of substrate 130, one or more reactant sources 110, 112, and/or 113, and/or a carrier and/or purge gas source 114, fluidly coupled to reaction chamber 104 via respective lines 116, 118, 119 and 120, and respective valves or controllers 122, 123, 125 and 126. Reactant species and/or precursors such as precursor 115, oxygen species 117, inhibitor 121, and plasma species 133 or other materials from respective sources 110, 112, 113, and/or 144 can be applied to substrate 130 in reaction chamber 104. Purge gas 124 from gas source 114 can be flowed to and through reaction chamber 104 to remove any excess reactant or other undesired materials from reaction chamber 104. Reactor system 150 may include a direct plasma source 179 incorporated within chamber 104 and/or a remote plasma source 170 coupled to chamber 104. System 150 can also comprise a vacuum source 128 fluidly coupled to the reaction chamber 104, which can be configured to evacuate reactants, a purge gas, or other materials out of reaction chamber 104.

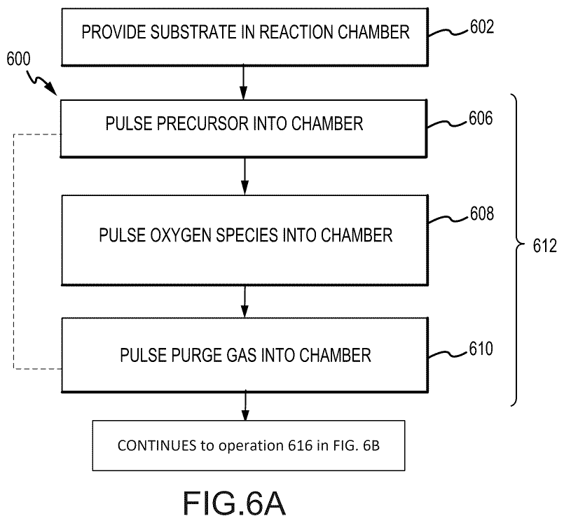

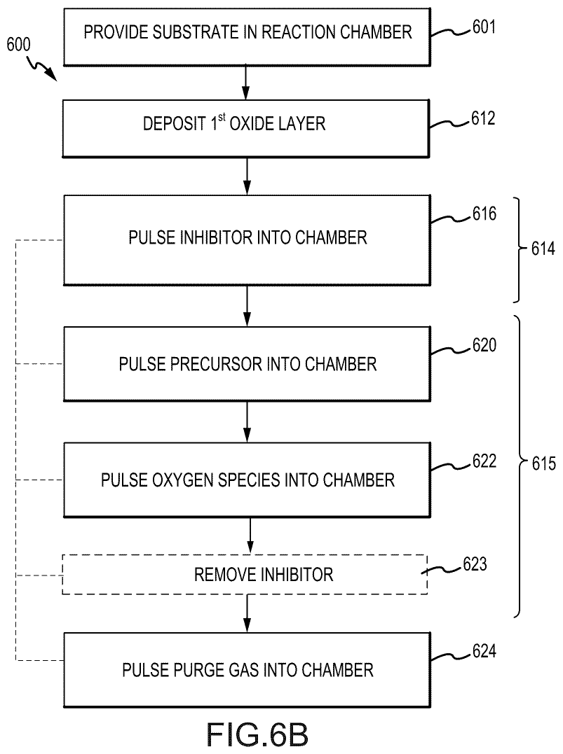

Controller 152 can be configured to perform various functions and/or steps as described herein. Controller 152 can include one or more microprocessors, memory elements, and/or switching elements to perform the various functions. Although illustrated as a single unit, controller 152 can alternatively comprise multiple devices. By way of example, controller 152 can be used to control gas flow (e.g., by monitoring flow rates and controlling valves 122, 123, 125, 126 and/or 127), motors, heaters, cooling devices and/or vacuum source 128 to execute various processes (e.g., methods 600, 700, 800 and/or 900 shown in respective FIGS. 6A, 6B, 7, 8 and/or 9). Further, when a system includes two or more reaction chambers, as described in more detail below, the two or more reaction chambers can be coupled to the same/shared controller or may have separate controllers.

In an example, a gap filling process may be performed to deposit an oxide within a recess 31 of substrate 130. The process may comprise pulsing precursor 115 from reactant source 110 to reaction chamber 104 via showerhead 108. Oxygen species 117 may be pulsed with or separately from precursor 115 from reactant source 112 to reaction chamber 104 via showerhead 108. As precursor 115 and oxygen species 117 contact substrate 130 an oxide may form on substrate 130 within recess 31. To inhibit deposition of metal oxide at the top and/or outside of the recess an inhibitor 121 may also be pulsed into chamber 104 from reactant source 113. Inhibitor 121 may be flowed into the chamber 104 separately from precursor 115 and/or oxygen species 117. In an example, inhibitor 121 may be flowed into chamber 104 subsequent to flowing precursor 115 and oxygen species 117 into chamber 104.

Inhibitor 121 may be selected to preferentially deposit on an oxide deposited at an opening of the recess 31 so as to prevent excess additional oxide from forming in the first area at the opening to the recess 31 or to a greater extent than within recess 31. Reduction in deposition at the opening of recess 31 may reduce formation of gaps or seams in oxide deposited therein.

In an example, oxide materials such as precursor 115 and oxygen species 117 may be deposited in the same chamber as inhibitor 121 or may be deposited in different chambers.

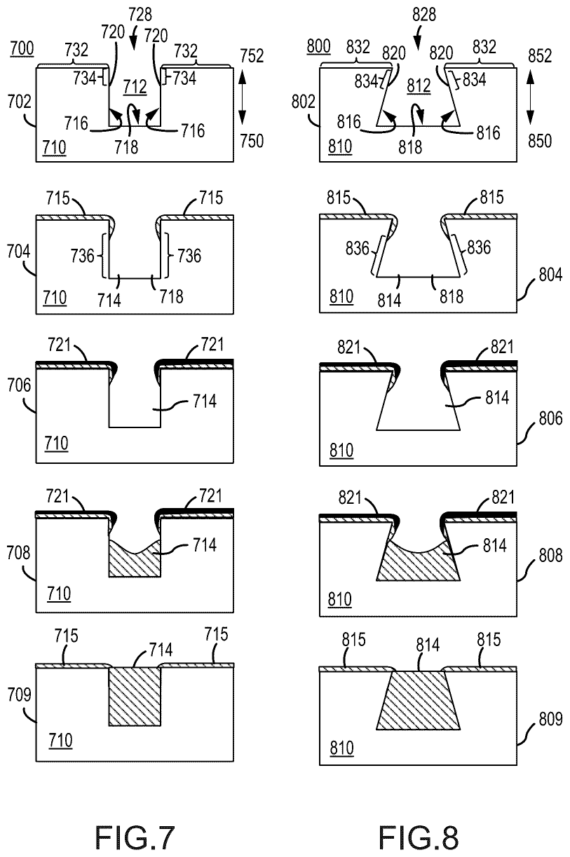

The oxide gap fill layer may be formed by any of a variety of methods including one or more deposition cycles or a super deposition cycle having two or more deposition sub-cycles. For example, a first deposition cycle or sub-cycle may include including pulsing precursor 115 and oxygen species 117 into the chamber to deposit the oxide preferentially in a first area near or proximate to the recess 31 opening and purging the chamber with a purge gas 124 between one or more pulses and/or between one or more first deposition cycles. Such a first deposition cycle (or portions thereof) may be repeated until a desired thickness of deposited first oxide layer is disposed in the first area. In a second deposition cycle, inhibitor 121 may be pulsed into chamber 104 and may selectively deposit onto the oxide layer in the first area. Inhibitor 121 may preferentially deposit on the oxide deposited compared to substrate 130 material (e.g., silicon oxide (SiOx)). In other words, inhibitor 121 has a higher affinity or selectivity for the oxide surfaces over the substrate surfaces. Inhibitor 121 deposition forms an inhibitor layer in the first area over the first oxide layer of a thickness not to obstruct the opening of recess 31, thus the thickness may be less than 50 angstroms, or less than 30 angstroms, or less than 20 angstroms, or less than 10 angstroms, or any appropriate thickness (e.g., inhibitor layer 721, 821, 921, see FIGS. 7, 8, 9). A third deposition cycle may include pulsing precursor 115 and oxygen species 117 into the chamber 104 to deposit the oxide preferentially in a second area within recess 31 and purging the chamber with a purge gas 124 between one or more pulses and/or between one or more third deposition cycles. Such a third deposition cycle (or portions thereof) may be repeated until a desired thickness of deposited second oxide layer is disposed in the second area.

First, second and third deposition cycles may be performed in the same reaction chamber (e.g., chamber 104) or one or more of first, second and third deposition cycles may be performed in different reaction chambers.

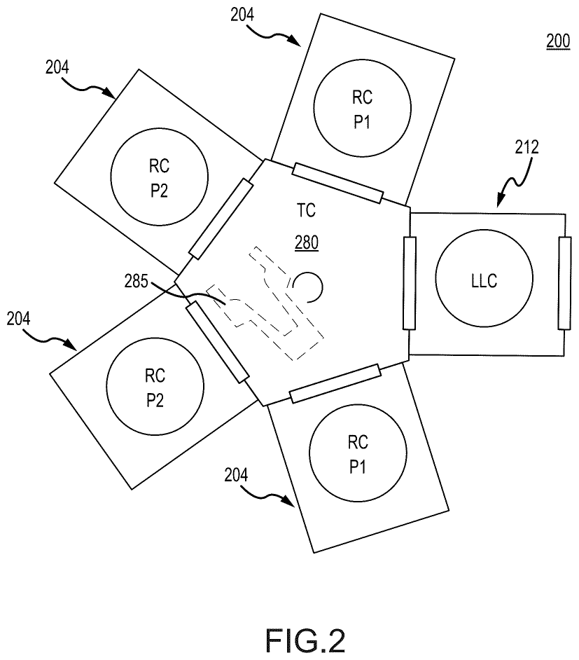

In some examples, a reactor system (e.g., reactor system 150) can comprise multiple reaction chambers. For example, in reactor system 200, shown in FIG. 2, a number of reaction chambers 204 (each of which can be an example of reaction chamber 104 in FIG. 1) can be disposed around and/or coupled to a transfer chamber 280 comprising a transfer tool 285 for transferring substrates between reaction chambers 204. Substrates can be transferred from a load lock chamber 212 and between reaction chambers 204 (e.g., through transfer chamber 280). For example, a substrate 130 can be disposed in different chambers for different steps of a semiconductor manufacturing process (e.g., etching, oxidizing, passivation and/or deposition steps may each be performed in the same or different chambers).

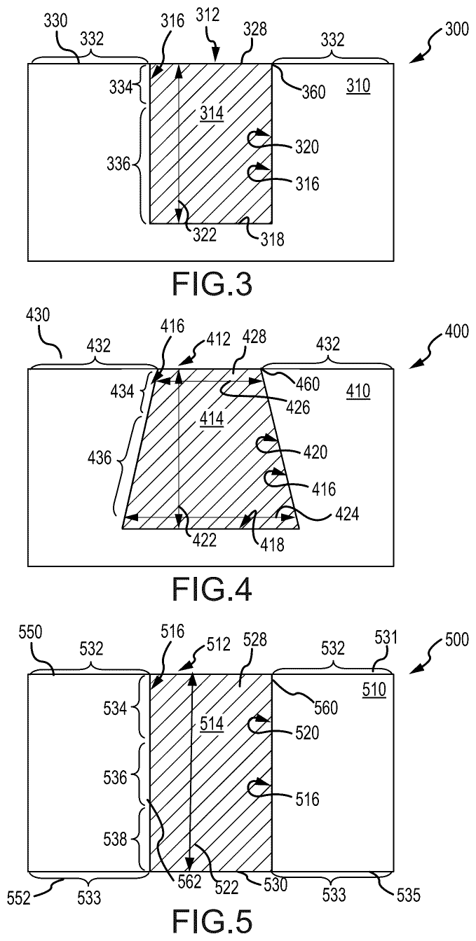

FIG. 3 illustrates a structure 300 in accordance with examples of the disclosure. Device structure 300 can be any of a variety of semiconductor structures. In various examples, substrate 310 features may be formed into or onto a surface 330 of substrate 310, for example, a three-dimensional structure such as a recess 312 may form a portion of a FinFET, Complementary Field-Effect Transistor (CFET) or gate-all-around (GAA) FET and/or a memory element. In some examples, structure 300 may have a high aspect ratio (e.g., aspect ratios of about 4 or higher) or complex morphology.

In an example, recess 312 may have a top portion 334 and a lower portion 336. Recess 312 may extend a depth 322 from opening 328 to lower surface 318 and may be filled with an oxide layer 314. Recess 312 may be bordered by a perimeter 360 in surface 330 about opening 328. An area bordering Recess 312 may also include inner surface 320 comprising sidewalls surfaces 316 and a lower surface 318. Opposing sidewalls 316 may be parallel. Structure 300 may be formed according to examples described herein.

FIG. 4 illustrates a structure 400 in accordance with examples of the disclosure. Device structure 400 can be any of a variety of semiconductor structures. In various examples, substrate 410 features may be formed into or onto a surface 430 of substrate 410, for example, a three-dimensional structure such as a recess, cavity, or trench, or a combination thereof. Such a patterned substrate 410 may comprise partially fabricated semiconductor device structures, such as, for example, transistors (e.g., such as FinFETS, gate-all-around (GAA) FETS, CFET and/or memory elements). In some examples the structures may have high aspect ratios (e.g., aspect ratios of about 4 or higher) or complex morphology.

In an example, structure 400 includes a substrate 410 having a recess 412. Recess 412 may have a top portion 434 and a lower portion 436. Recess 412 may be filled with an oxide 414. Recess 412 may be bordered by a perimeter 460 in surface area 432 near opening 428. Recess 412 may also include inner surface 420 comprising sidewalls surfaces 416 and a lower surface 418. Recess 412 may extend a depth 422 into recess 412. Opposing sidewalls 416 may be angled such that recess 412 is an inverse taper extending from opening 428 to lower surface 418. In such an example, width 424 of lower surface 418 is greater than width 426 of opening 428. Structure 400 may be formed according to examples described herein.

FIG. 5 illustrates a structure 500 in accordance with examples of the disclosure. Device structure 500 can be any of a variety of semiconductor structures (e.g., gate-all-around (GAA) structure). In various examples, substrate 510 features may be formed into or onto a surface 531 and/or 535 of substrate 510 (e.g., a three-dimensional structure such as a hole or via). Such a patterned substrate 510 may comprise partially fabricated semiconductor device structures, such as, for example, transistors (e.g., such as FinFETS or gate-all-around (GAA) FETS) and/or memory elements. In some examples the structures may have high aspect ratios (e.g., aspect ratios of about 4 or higher) or complex morphology.

In an example, structure 500 includes a substrate 510 having a recess 512. Recess 512 may have outer portions 534 and 538 and an inner portion 536. Recess 512 may be filled with an oxide 514. Recess 512 may be bordered on a first side 550 by a perimeter 560 in surface area 532 and on an opposite side 552, recess 512 may be bordered by perimeter 562 in surface area 533. Surface area 532 may be disposed in a plane about perimeter 560 of recess 512 proximate opening 528. Surface area 533 may be disposed in a plane about perimeter 562 of recess 512 near opening 530. Recess 512 may also include an inner surface 520 comprising sidewalls surfaces 516. Recess 512 may extend a depth of 522 from opening 528 through to opening 530 to form a hole or via in substrate 510. Opposing sidewall surfaces 516 may be parallel or have a different geometry. Structure 500 may be formed according to examples described herein.

Referring to FIGS. 3, 4, and 5, in some examples, the substrate comprises silicon oxide (SiOx) and surfaces (e.g., sidewall surface 316, lower surface 318, sidewall surface 416, lower surface 418, sidewall surface 516, see FIGS. 3, 4, 5) within the recess (e.g., recesses 312, 412, 512, see FIGS. 3, 4, 5) comprise silicon oxide. In some examples, the structures 300, 400, and/or 500 (see FIGS. 3, 4, 5) form at least a portion of a semiconductor device having a finFET, GAA or CFET architecture.

FIG. 6A (with reference to FIGS. 1-9) illustrates a first deposition cycle 612 of an example process 600 for depositing an oxide in a recess of a substrate to form a semiconductor structure (e.g., structure 300, 400 and/or 500 illustrated in respective FIGS. 3, 4 and 5) in accordance with examples of the disclosure.

In an example, process 600 may begin at operation 602 with provision of a substrate (e.g., substrate 130, 310, 410 and/or 510 illustrated in respective FIGS. 1, 3, 4, and/or 5) within a chamber (e.g., chamber 104 illustrated in FIG. 1). The substrate may be disposed on a susceptor (e.g., susceptor 106 in FIG. 1) for processing. The substrate may include at least one opening (e.g., opening 328, 428, 528 and/or 530 illustrated in respective FIGS. 3, 4, and/or 5) to a recess (e.g., recess 31, 328, 428, and/or 528 illustrated in respective FIGS. 1, 3, 4, and/or 5). The recess may comprise at least one opening bordered by a perimeter (e.g., perimeter 360, 460, 560, and/or 562 illustrated in respective FIGS. 3, 4, and/or 5) in a surface area (e.g., surface area 332, 432, 532, and/or 533 illustrated in respective FIGS. 3, 4, and/or 5) adjacent to and outside of the recess, wherein the recess comprises an inner surface (e.g., inner surface 320, 420 and/or 520 illustrated in respective FIGS. 3, 4, and/or 5).

In an example, process 600 may move to operation 606 of first deposition cycle 612 where a precursor 115 may be pulsed into the chamber where the precursor 115 may deposit in a first area proximate to the opening (e.g., opening 328, 428, 528 and/or 530 illustrated in respective FIGS. 3, 4, and/or 5). In an example, the “first area” comprises a surface area about a perimeter of the opening (e.g., surface area 332, 432, 532, and/or 533 illustrated in respective FIGS. 3, 4, and/or 5) and a top portion (e.g., top portions 334 or 434 and/or outer portions 534 and/or 538 illustrated in respective FIGS. 3, 4, and/or 5) of the inner surface (e.g., inner surface 320, 420, and/or 520 illustrated in respective FIGS. 3, 4, and/or 5) within the recess (e.g., recess 312, 412 and/or 512).

In an example, precursor 115 can be provided through a showerhead (e.g., showerhead 108 illustrated in FIG. 1) to the substrate, or through a crossflow fluid distribution system. In an example, precursor 115 may be a metal-containing precursor for forming of metal or metallic oxides including but not limited to aluminum oxide (AlxOy), magnesium oxide (MgO), aluminum oxide (Al2O3), zirconium oxide (ZrO2), hafnium oxide (HfO₂), hafnium silicon oxide (HfSiO), tantalum oxide (Ta2O5), tantalum silicon oxide (TaSiO), titanium dioxide (TiO2), zinc oxide (ZnO), barium strontium titanate (BST), and strontium bismuth tantalate (SBT). Such precursors may comprise, for example, trimethylaluminum (TMA), dimethylaluminum hydride (DMAH), dimethylaluminum isopropoxide (DMAI), dimethylethylaminealane (DMEAA), trimethylaminealane (TEAA), N-methylpyrroridinealane (MPA), tri-isopropoxide aluminum, tri-isobutylaluminum (TIBA), and tritertbutylaluminum (TTBA), diethyl zinc (DEZ), tetraisopropyl orthotitanate (TTIP), titanium tetrachloride (TiCl4), tetrakis (dimethylamino) titanium (TDMAT), tetrakis(dimethylamino) zirconium (IV) (TDMAZ), magnesocene (Mg—(Cp)2), dimethylzinc (ZnMe2), diethylzinc (ZnEt2), methylzinc isopropoxide (ZnMe(OPr)), or zinc acetate (Zn(CH3CO2)2, halfnium chloride (HfC14), and/or zirconium (IV) chloride (ZrC14), or the like or combinations thereof, or any other appropriate precursor.

In other examples, precursor 115 may be a lanthanide-containing precursor for forming of lanthanide oxides, i.e., oxides of physically stable “rare earth” metallic elements such as scandium (Sc), yttrium (Y), lanthanum (La), cerium Ce, praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb) and lutetium (Lu), as well as silicon nitride (SiN). Such precursors may comprise, for example, 2,2,6,6-tetramethyl-3,5-heptane-dionate (III) lanthanum (La(thd)3), tris(cyclopentadienyl) lanthanum (III) (La(Cp)3), tris(isopropylcyclopentadienyl) lanthanum (III) (La(iPrCp)3) and/or tris(N,N′-diisopropylacetamidinato) scandium (Sc(amd)3), or the like or combinations thereof, or any other appropriate precursor. In an exemplary embodiment, the precursor 115 comprises TMA.

In an example, precursor 115 can be pulsed into the reaction chamber for any suitable duration (e.g., for pulse times of between 0.05 to 200 seconds). The pressure within the reaction chamber during provision of precursor 115 can be any suitable pressure, such as between 1 and 10 Torr. The temperature during pulsing of precursor 115 can be between about 100° C. and 500° C., or about 450° C., or between about 100° C. and 400° C., or about 350° C. or between about 100° C. and 300° C., or about 250° C., or between about 100° C. and 200° C., or about 150° C. (“about” in this context means plus or minus 50° C.) or any sufficient temperature.

In an example, process 600 may proceed to operation 608 where oxygen species 117 may be pulsed into the chamber to contact substrate and form the first oxide layer (e.g., oxide layer 715, 815 and/or 915, see respective FIGS. 7, 8, and 9) in the first area (noted above). Exposing the substrate to oxygen species 117 then allows the oxygen-containing species to react with the chemisorbed precursor to form an oxide. In an example, oxygen species 117 may comprise any suitable compound comprising oxygen and/or an oxidizing compound, such as water (H2O), ozone (O3), hydrogen peroxide (H2O2), deuterium oxide (D2O), nitrous oxide (N2O), nitrogen dioxide (NO2), and/or an alcohol (e.g., tertbutyl alcohol), or the like or combinations thereof. In an exemplary embodiment, the oxygen species 117 comprises H2O.

In some embodiments, pulsing the oxygen species 117 into the reaction chamber may comprise contacting the substrate 130 for a time period of between about 0.01 seconds and about 200 seconds, or between about 0.01 seconds and about 180 seconds, or between about 0.01 seconds and about 160 seconds, or between about 0.01 seconds and about 140 seconds, or between about 0.01 seconds and about 120 seconds, or between about 0.01 seconds and about 100 seconds, or between about 0.01 seconds and about 80 seconds, or between about 0.01 seconds and about 60 seconds, or between about 0.01 seconds and about 50 seconds, or between about 0.01 seconds and about 30 seconds, or between about 0.01 seconds and about 20 seconds, or between about 0.01 seconds and about 10 seconds, or between about 0.01 seconds and about 5.0 seconds (“about” in this context means plus or minus 10 seconds) or any other suitable duration.

The temperature during pulsing of oxygen species 117 can be between about 100° C. and 500° C., or about 450° C., or between about 100° C. and 400° C., or about 350° C. or between about 100° C. and 300° C., or about 250° C., or between about 100° C. and 200° C., or about 150° C. (“about” in this context means plus or minus 50° C.) or any sufficient temperature.

In an example, the first oxide layer may be any appropriate thickness, for example, in the range of about 5 Å-30 Å, or about 6 Å-25 Å, or about 7 Å-20 Å, or about 8 Å-15 Å, about 8 Å-12 Å.

In an example, process 600 may move to operation 610 of first deposition cycle 612 where the steps of providing precursor 115 at operation 606 and providing oxygen species 117 at operation 608 can each be separated by a purge gas 124 to remove excess precursor, byproducts, or other unwanted materials. In various examples, a purge gas can be provided after each operation (e.g., after pulsing precursor 115 and/or oxygen species 117) and/or after first deposition cycle 612. In an exemplary embodiment, the first oxide layer comprises aluminum oxide.

FIG. 6B (with reference to FIGS. 1-9) illustrates a second deposition cycle 614 and a third deposition cycle 615 of an example process 600 for depositing an oxide in a recess of a substrate to form a semiconductor structure (e.g., structure 300, 400 and/or 500 illustrated in respective FIGS. 3, 4 and 5) in accordance with examples of the disclosure.

In an example, process 600 may move to operation 616 of second deposition cycle 614 where inhibitor 121 may be pulsed into chamber 104 and may selectively deposit onto the first oxide layer in the first area. Inhibitor 121 may preferentially deposit on the oxide deposited in the first area compared to substrate 130 material (e.g., silicon oxide (SiOx)). In other words, inhibitor 121 has a higher affinity or selectivity for the metal oxide surfaces over the substrate surfaces. In an example, inhibitor 121 may comprise a self-assembled monolayer, for example, Octadecylphosphonic acid (ODPA), Octadecyltrichlorosilane (OTS), Perfluorodecyltrichlorosilane (FDTS), alkylphosphonic acids, arylphosphonic acids, and aminophosphonic acids, or carboxylic acids.

A self-assembled monolayer (SAM), such as, Octadecylphosphonic acid (ODPA) can be selected to block the adsorption of precursor 115 (e.g., TMA) and thus inhibit further growth of metal oxide (e.g., AlOx) around the opening of recess (e.g., recess 312). By doing so a lower heavy or middle heavy growth profile might be achieved which is preferable to keep the entrance to the recess open throughout the gapfill process.

In some embodiments, contacting substrate 130 with an inhibitor 121 may comprise contacting the substrate 130 for a time period of between about 0.01 seconds and about 200 seconds, or between about 0.01 seconds and about 180 seconds, or between about 0.01 seconds and about 160 seconds, or between about 0.01 seconds and about 140 seconds, or between about 0.01 seconds and about 120 seconds, or between about 0.01 seconds and about 100 seconds, or between about 0.01 seconds and about 80 seconds, or between about 0.01 seconds and about 60 seconds, or between about 0.01 seconds and about 50 seconds, or between about 0.01 seconds and about 30 seconds, or between about 0.01 seconds and about 20 seconds, or between about 0.01 seconds and about 10 seconds, or between about 0.01 seconds and about 5.0 seconds (“about” in this context means plus or minus 10 seconds) or any other suitable duration.

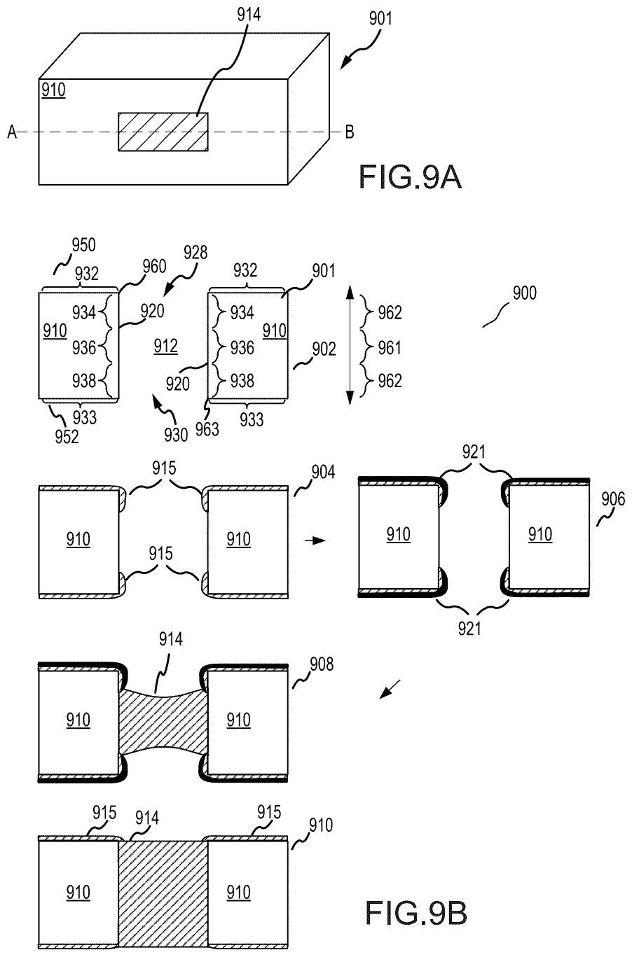

In an example, process 600 may proceed to operation 620 of third deposition cycle 615 where a second oxide layer may be deposited in a second area. In an example, precursor 115 may be pulsed into the chamber. Precursor 115 may chemisorb or be deposited in the second area within at least a portion of the recess. In an example, the “second area” comprises surfaces and a volume within at least a lower portion (e.g., lower surface 736, lower portion 836, see FIGS. 7,8) or a middle portion (e.g., middle portion 936, see FIG. 9) of the recess (e.g., recess 712, 812 and/or 912) including surfaces therein (e.g., side surface 716, lower surface 718, side surface 816, lower surface 818, a middle portion 936, side surfaces 920, see FIGS. 7, 8, 9).

In an example, precursor 115 can be provided through a showerhead (e.g., showerhead 108 illustrated in FIG. 1) to the substrate, or through a crossflow fluid distribution system. Precursor 115 may comprise metal precursors as discussed hereinabove.

At operation 622, oxygen species 117 may be pulsed into the chamber to form a second oxide layer (e.g., second oxide layer 714, 814 and/or 914) in the second area, at least partially filling the volume therein. The inhibitor layer (e.g., inhibitor layer 721, 821, 921) inhibits deposition of the second oxide layer in the first area.

Second oxide layer (e.g., second oxide layer 714, 814 and/or 914, see FIGS. 7, 8, 9) may be formed responsive to oxygen species 117 contacting chemisorbed precursor 115 in the second area. Over a number of repeating third deposition cycles 615 the second oxide layer may fill the recess (e.g., recess 712, 812, and/or 912 illustrated in respective FIGS. 7, 8, 9) to a depth at least equal to the length of the recess (e.g., depth 322, 422, 522, see FIGS. 3, 4, 5). Oxygen species 117 may comprise oxygen species as discussed hereinabove. As noted previously, because more precursor 115 may be chemisorbed in the lower region of the recess compared to the top portion, second oxide layer may be formed more readily and grow more rapidly in the lower portions, or middle portions (e.g., lower portion 736, lower portion 836, outer portions 936 and 938, see FIGS. 7, 8, 9) compared to the upper or outer region (e.g., upper portion 734, upper portion 834, middle portion 936, see FIGS. 7, 8, 9) over one or more third deposition cycles 615. Thus, second oxide layer (e.g., oxide layer 314 and/or 414 illustrated in respective FIGS. 3 and 4) may be grown in a bottom-up way and/or may be grown from side surfaces inward and from a middle portion outward (e.g., second oxide layer 914 grown from middle portion 936 outward toward outer portions 934 and 938 and inward from side surfaces 920, see FIG. 9). The steps of pulsing precursor 115, oxygen species 117 in respective operations 606, 608, 620, and 622 can be performed in any suitable order.

At operation 623, inhibitor layer (e.g., 721, 821, 921, see FIGS. 7. 8. 9) may be removed by exposing the substrate 130, for example, to a removal agent such as an H2 plasma (e.g., plasma reactant 133), O3 and/or H2O.

At operation 624, in various examples, the steps of providing precursor 115 at operations 606 and 620, providing oxygen species 117 at operations 608 and 622, providing inhibitor 121 at operation 616, and inhibitor removal at operation 623 can each be separated by a purge gas 124 (operations 610 or 624) to remove excess precursor, byproducts, or other unwanted materials. In various examples, a purge gas can be provided after each operation (e.g., after pulsing precursor 115, oxygen species 117, removal agent and/or inhibitor 121, regardless of the order) and/or after deposition of the oxide layer (e.g., oxide layer 314, 414, and/or 514).

In various examples, the steps of providing precursor 115, oxygen species 117 and inhibitor 121 can be performed in any suitable order. For example, one or more of the steps of pulsing precursor 115, oxygen species 117 and inhibitor 121 can be performed sequentially and/or simultaneously. One or more steps of pulsing precursor 115, oxygen species 117 and/or inhibitor 121 into the chamber may be separated by a purge gas 124 to remove excess precursor, byproducts, or other unwanted materials. In various examples, a purge gas 124 can be provided after each step (e.g., after providing the precursor 115 and providing the oxygen species 117, regardless of the order) and/or after each deposition cycle 612, 614, 615 and/or after deposition of the oxide or after a deposition of inhibitor.

In some embodiments, contacting substrate 130 with an oxygen species 117 may comprise pulsing the oxygen species 117 into the reaction chamber and subsequently contacting the substrate 130 for a time period of between about 0.01 seconds and about 200 seconds, or between about 0.01 seconds and about 180 seconds, or between about 0.01 seconds and about 160 seconds, or between about 0.01 seconds and about 140 seconds, or between about 0.01 seconds and about 120 seconds, or between about 0.01 seconds and about 100 seconds, or between about 0.01 seconds and about 80 seconds, or between about 0.01 seconds and about 60 seconds, or between about 0.01 seconds and about 50 seconds, or between about 0.01 seconds and about 30 seconds, or between about 0.01 seconds and about 20 seconds, or between about 0.01 seconds and about 10 seconds, or between about 0.01 seconds and about 5.0 seconds (“about” in this context means plus or minus 10 seconds) or any other suitable duration.

Pulsing of precursor 115, oxygen species 117 and inhibitor 121 may be alternating, sequential, and/or simultaneous. One or more of precursor 115, oxygen species 117 and inhibitor 121 may be pulsed over about 1 cycle to about 200 cycles, or about 1 cycle to about 180 cycles, or about 1 cycle to about 160 cycles, or about 1 cycle to about 140 cycles, or about 1 cycle to about 120 cycles, or about 1 cycle to about 100 cycles, or about 1 cycle to about 80 cycles, or about 1 cycle to about 60 cycles, or about 1 cycle to about 40 cycles, or about 1 cycle to about 20 cycles, about 1 cycle to about 5 cycles, (“about” in this context means plus or minus 20 cycles) or any suitable number of cycles.

FIG. 7 illustrates an example process 700 for forming a semiconductor structure in accordance with examples of the disclosure. In an example, process 700 may begin at operation 702 with provision of a substrate 710 within a chamber (e.g., chamber 104 illustrated in FIG. 1).

Substrate 710 may be disposed on a susceptor (e.g., susceptor 106 in FIG. 1) for processing. Substrate 710 may include at least one opening 728 to a recess 712. In an example, opening 728 is bordered by a perimeter surface area 732. Recess 712 comprises an side surface 716.

Process 700 may move to operation 704 where first deposition cycle 612 (see FIG. 6A) may include pulsing of precursor 115 and oxygen species 117 (separately or together, or a combination thereof) into chamber 104 to contact substrate 710 and deposit a thin layer of oxide, first layer 715 in a first area, wherein the first area comprises at least a portion of the perimeter surface area 732 and at least a portion of the top portion 734 of recess 712.

Process 700 may move to operation 706 where a second deposition cycle 614 (see FIG. 6B) may include pulsing of inhibitor 121 into the chamber where inhibitor 121 may contact first oxide layer 715. In an example, inhibitor 121 can be pulsed into the reaction chamber for any suitable duration (e.g., for pulse times of between 0.05 to 200 seconds).

In some examples, inhibitor 121 selectively deposits an inhibitor layer 721 on first oxide layer 715 preferentially against the material comprising the substrate 710 such as silicon oxide. Inhibitor 121 is a growth inhibitor as described above in more detail. In an example, deposition of inhibitor 121 is selective thus inhibitor 121 deposits preferentially in the first area over first oxide layer 715. This positioning of the inhibitor produces an inhibitory effect in the first area at and/or near opening 728 enabling a higher growth rate of second oxide layer 714 at the lower surface 718, and/or lower portion 736 during the subsequent third deposition cycle 615 (see FIG. 6B) in operation 708.

Operation 708 may include pulsing of precursor 115 and oxygen species 117 (separately or together, or a combination thereof) into chamber 104 to contact substrate 710 and deposit a layer of oxide, second oxide layer 714 in a second area, wherein the second area comprises at least a portion of the lower surface 718 and at least a portion of lower portion 736 of recess 712.

In an example, precursor 115 can be provided through a showerhead (e.g., showerhead 108 illustrated in FIG. 1) to the substrate, or through a crossflow fluid distribution system. In an example, precursor 115 may be a precursor as described above. Precursor 115 may chemisorb to the inner surface 720 within the recess 712. Exposing the substrate 710 to an oxygen reactant 117 then allows oxygen-containing species to react with the chemisorbed precursor to form a metal oxide. Because more precursor 115 may be chemisorbed preferentially in the distal region 750 compared to the proximate region 752 due to the presence of the inhibitor 121 in the first area, more metal oxide may be formed in the distal region compared to the proximal region. In other words, the metal oxide may be grown in a bottom-up way. At operation 708, third deposition cycle 615 may be repeated a number of times sufficient for oxide layer 714 to fill recess 712 substantially free of gaps or seams.

Process 700 may proceed to operation 709 where inhibitor layer 721 may be removed, for example by an H2 plasma (plasma reactant 133), O3 and/or H2O. First oxide layer 715 may remain on surface 732 or may be removed by any appropriate method. In an example, a thickness of the second oxide layer may be about a height of the recess from the top of opening 728 to a lower surface 718.

FIG. 8 illustrates an example process 800 for forming a semiconductor structure in accordance with examples of the disclosure. In an example, process 800 may begin at operation 802 with provision of a substrate 810 within a chamber (e.g., chamber 104 illustrated in FIG. 1).

Substrate 810 may be disposed on a susceptor (e.g., susceptor 106 in FIG. 1) for processing. Substrate 810 may include at least one opening 828 to a recess 812. In an example, opening 828 is bordered by a perimeter surface area 832. Recess 812 comprises an side surface 816.

Process 800 may move to operation 804 where first deposition cycle 612 (see FIG. 6A) may include pulsing of precursor 115 and oxygen species 117 (separately or together, or a combination thereof) into chamber 104 to contact substrate 810 and deposit a thin layer of oxide 815 in a first area, wherein the first area comprises at least a portion of the perimeter surface area 832 and at least a portion of the top portion 834 of recess 812. Recess 812 may be an inverse taper shape.

Process 800 may move to operation 806 where a second deposition cycle 614 (see FIG. 6B) may include pulsing of inhibitor 121 into the chamber where inhibitor 121 may contact first oxide layer 815. In an example, inhibitor 121 can be pulsed into the reaction chamber for any suitable duration (e.g., for pulse times of between 0.05 to 200 seconds).

In some examples, inhibitor 121 selectively deposits an inhibitor layer 821 on first oxide layer 815 preferentially against the material comprising the substrate 810 such as silicon oxide. Inhibitor 121 is a growth inhibitor as described above in more detail. In an example, deposition of inhibitor 121 is selective thus inhibitor 121 deposits preferentially in the first area over first oxide layer 815. This positioning of the inhibitor produces an inhibitory effect in the first area at and/or near opening 828 enabling a higher growth rate of a second oxide layer 814 at the lower surface 818, and/or lower portion 836 during the subsequent third deposition cycle 615 (see FIG. 6B) in operation 808.

Operation 808 may include pulsing of precursor 115 and oxygen species 117 (separately or together, or a combination thereof) into chamber 104 to contact substrate 810 and deposit a second oxide layer 814 in a second area, wherein the second area comprises at least a portion of the lower surface 818 and at least a portion of lower portion 836 of recess 812.

In an example, precursor 115 can be provided through a showerhead (e.g., showerhead 108 illustrated in FIG. 1) to the substrate, or through a crossflow fluid distribution system. In an example, precursor 115 may be a precursor as described above. Precursor 115 may chemisorb to the inner surface 820 within the recess 812. Exposing the substrate 810 to an oxygen reactant 117 then allows oxygen-containing species to react with the chemisorbed precursor to form a metal oxide. Because more precursor 115 may be chemisorbed preferentially in the distal region 850 compared to the proximate region 852 due to the presence of the inhibitor 121 in the first area, more metal oxide may be formed in the distal region compared to the proximal region. In other words, the metal oxide may be grown in a bottom-up way. At operation 808, third deposition cycle 615 may be repeated a number of times sufficient for second oxide layer 814 to fill recess 812 substantially free of gaps or seams.

Process 800 may proceed to operation 809 where inhibitor layer 821 may be removed, for example by a plasma. First oxide layer 815 may remain on surface 832 or may be removed by any appropriate method.

FIG. 9A illustrates a structure 901 in accordance with examples of the disclosure. Device structure 901 can be any of a variety of semiconductor structures (e.g., gate-all-around (GAA) structure). In various examples, various features may be formed into or onto a surface of substrate 910 (e.g., a three-dimensional structure such as a hole or via). Such a patterned substrate 910 may comprise partially fabricated semiconductor device structures, such as, for example, transistors (e.g., such as FinFETS or gate-all-around (GAA) FETS) and/or memory elements. In some examples the structures may have high aspect ratios (e.g., aspect ratios of about 4 or higher) or complex morphology.

FIG. 9B illustrates an example process 900 for forming a semiconductor structure 901 in accordance with examples of the disclosure. Cross-sectional view A-B from FIG. 9A is shown with process operations 902-908 in FIG. 9.

In an example, process 900 may begin at operation 902 with provision of a substrate 910 within a chamber (e.g., chamber 104 illustrated in FIG. 1). In an example, structure 901 includes a recess 912. Recess 912 may have outer portions 934 and 938 and a middle portion 936.

Recess 912 has openings 928 and 930. In an example, opening 928 is bordered by a perimeter in surface area 932. In an example, opening 930 is bordered by a perimeter in surface area 933. Recess 912 extends from opening 928 to opening 930 and comprises an inner surface 920.

Substrate 910 may include an opening bordered on a first side 950 by a perimeter 960 in surface area 932. On an opposite side 952, recess 912 may be bordered by perimeter 963 in surface area 933. Surface area 932 may be disposed in a plane about perimeter 960 of recess 912 proximate opening 928. Surface area 933 may be disposed in a plane about perimeter 963 of recess 912 near opening 930. Recess 912 may also include an inner sidewall surface 920 comprising sidewalls surfaces. Recess 912 may extend from opening 928 through to opening 930 to form a hole or via in substrate 910. Opposing sidewall surfaces 920 may be parallel or have a different geometry. Structure 901 may be formed according to examples described herein.

Process 900 may move to operation 904 where first deposition cycle 612 (see FIG. 6A) may include pulsing of precursor 115 and oxygen species 117 (separately or together, or a combination thereof) into chamber 104 to contact substrate 910 and deposit a thin layer of oxide 915 in a first area, wherein the first area comprises at least a portion of the perimeter surface area 932, at least a portion of perimeter surface area 932, at least a portion of outer portions 934 and 938 of recess 912.

Process 900 may move to operation 906 where a second deposition cycle 614 (see FIG. 6B) may include pulsing of inhibitor 121 into the chamber where inhibitor 121 may contact oxide 915. In an example, inhibitor 121 can be pulsed into the reaction chamber for any suitable duration (e.g., for pulse times of between 0.05 to 200 seconds).

In some examples, inhibitor 121 selectively deposits an inhibitor layer 921 on oxide 915 preferentially against the material comprising the substrate 910 such as silicon oxide. Inhibitor 121 is a growth inhibitor as described above in more detail. In an example, deposition of inhibitor 121 is selective thus inhibitor 121 deposits preferentially in the first area near over oxide 915. This positioning of the inhibitor produces an inhibitory effect in the first area at and/or near opening 928 and 930 enabling a higher growth rate of a second oxide layer 914 at sidewall 920 in middle portion 936, during the subsequent third deposition cycle 615 (see FIG. 6B) in operation 908.

Operation 908 may include pulsing of precursor 115 and oxygen species 117 (separately or together, or a combination thereof) into chamber 104 to contact substrate 910 and deposit the second layer of oxide 914 in a second area, wherein the second area comprises at least a middle portion 936 of recess 912.

In an example, precursor 115 can be provided through a showerhead (e.g., showerhead 108 illustrated in FIG. 1) to the substrate, or through a crossflow fluid distribution system. In an example, precursor 115 may be a precursor as described above. Precursor 115 may chemisorb to the inner surface 920 within the recess 912. Exposing the substrate 910 to an oxygen reactant 117 then allows oxygen-containing species to react with the chemisorbed precursor to form a metal oxide. Because more precursor 115 may be chemisorbed preferentially in the distal region 961 compared to the proximate regions 962 due to the presence of the inhibitor 121 in the first area, more metal oxide may be formed in the distal region 961 compared to the proximal region. Thus, the oxide may be grown inward from the inner side walls surface 920 and from middle 936 outward, substantially without seams or gaps. At operation 910, third deposition cycle 615 may be repeated a number of times sufficient for oxide layer 914 to fill recess 912 substantially free of gaps or seams.

Process 900 may proceed to operation 910 where inhibitor layer 921 may be removed, for example by a plasma. First oxide layer 915 may remain on surfaces 932 and 933 or may be removed by any appropriate method. In an example, a thickness of the second oxide layer 914 may be about a length of the recess 912 from the top of opening 728 to a lower surface 718.

Although exemplary examples of the present disclosure are set forth herein, it should be appreciated that the disclosure is not so limited. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A method for depositing an oxide in a recess of a substrate, comprising:
a) providing the substrate in a chamber, the substrate including at least one opening to the recess;
b) initially pulsing a precursor into the chamber to preferentially chemisorb in a first area;
c) pulsing an oxygen species into the chamber to form a first oxide layer in the first area upon contact with the chemisorbed precursor;
d) pulsing an inhibitor into the chamber to preferentially deposit an inhibitor layer on the first oxide layer;
e) pulsing the precursor into the chamber to chemisorb to a second area;
f) pulsing the oxygen species into the chamber to form a second oxide layer in the second area upon contact with the chemisorbed precursor; and
g) repeating one or more steps b)-c) until the first oxide layer is deposited to a first desired thickness in the first area;
h) repeating step d) until the inhibitor layer is deposited to a second desired thickness in the first area;
i) repeating steps e)-f) after deposition of the inhibitor until the second oxide layer is deposited to a third desired thickness in the second area.

2. The method of claim 1, wherein the first area is proximate to an opening of the recess.

3. The method of claim 1, wherein the second area is within the recess.

4. The method of claim 1, wherein the inhibitor is octadecylphosphonic acid.

5. The method of claim 1, wherein the precursor is a metal precursor.

6. The method of claim 5, wherein the metal precursor is TMA.

7. The method of claim 1, wherein the oxide is a metal oxide.

8. The method of claim 7, wherein the metal oxide is aluminum oxide.

9. The method of claim 1, wherein the oxygen species is H2O.

10. The method of claim 1, further comprising pulsing an inert gas into the chamber to purge the chamber subsequent to one or more of steps b)-f).

11. The method of claim 1, further comprising removing the inhibitor layer.

12. The method of claim 1, further comprising exposing the substrate to H2 plasma, O3 or H2O to remove the inhibitor layer.

13. The method of claim 1, wherein the first desired thickness is less than 20 angstroms,

14. The method of claim 1, wherein the first desired thickness is less than 15 angstroms,

15. The method of claim 1, wherein the second desired thickness is equivalent to a height of the recess from an opening to a lower surface.

16. The method of claim 1, wherein the second desired thickness is equivalent to a length of the recess from a first opening to a second opening.

17. A structure formed according to a method of claim 1.

18. The structure of claim 17, wherein the substrate comprises silicon oxide.

19. The structure of claim 17, wherein surfaces within the recess comprise silicon oxide.

20. The structure of claim 17, wherein the structure is a semiconductor device having a finFET, GAA or CFET architecture.
